(19) United States
(12) Patent Application Publication
(10) Pub. No.: US 2006/0178009 A1
(43) Pub. Date: Aug. 10, 2006

(54) Wafer stage with wafer positioning and alignment

(75) Inventor: Keiichi Tanaka, Saitama-city (JP)

Correspondence Address: KLARQUIST SPARKMAN, LLP, 121 SW SALMON STREET, SUITE 1600, PORTLAND, OR, 97204, US

(73) Assignee: Nikon Corporation

(21) Appl. No.: 11/286,366

(22) Filed: Nov. 23, 2005

(30) Foreign Application Priority Data
Nov. 26, 2004 (JP) 2004-342541

(51) Int. Cl. C23C 14/00; H01L 21/302

(52) U.S. Cl. 438/704; 118/50.1

(57) ABSTRACT

Stage devices are disclosed for positioning a wafer or other substrate. Also disclosed are exposure systems that include such a stage device. The stage devices improve the accuracy and precision with which the wafer, adhesion-chucked to a chuck mounted to the stage device, is positioned. The stage devices also facilitate removal of the substrate from the chuck. In an exemplary stage device a chuck is used to hold a substrate transported thereto by a transport means (e.g., robotic arm). The substrate is held on an upward-facing adhesion-chucking face of the chuck, which is mounted on a fine-movement table positioned above (and movable relative to) a coarse-movement stage. At least one support member, configured to remove the substrate from the chuck and to support the substrate in an upward direction whenever the fine-movement table is in a lowered position, is mounted to the coarse-movement stage.

### FIELD

This disclosure relates to stage devices on which a wafer or other substrate is placed for lithographic exposure or other processing, and to exposure systems including or using such a stage device.

### BACKGROUND

In general, in apparatus for electron-beam lithography (EBL), electron-projection lithography (EPL), extreme-ultraviolet lithography (EUVL) and in other exposure systems (as discussed in, e.g., Japan Laid-open (Kôkai) Patent Publication No. 2004-146718), a wafer stage is housed in a vacuum environment, and a robotic transport arm is used to transport the wafer to a chuck on the wafer stage. During transport of a wafer to a wafer stage located in a vacuum environment, the transport arm must be configured to extend through a narrow path. This is problematic because the rigidity of an extended transport arm is comparatively low, which creates difficulty in using the transport arm to position the wafer on the wafer stage with high precision.

After exposure is completed, the exposed wafer is retrieved from the chuck on the wafer stage using the transport arm. Significant time is consumed in overcoming the residual adhesion-chucking force of the chuck to allow removal of the wafer from the chuck. The cumulative effect of this time is reduced throughput.

### SUMMARY

This invention was devised in order to resolve these problems of the prior art, and has as an object the provision of a wafer-stage device and exposure system that improve the accuracy and precision with which a substrate is positioned and adhesion-chucked on a chuck on the wafer stage, and that allow easy removal of the substrate from the chuck.

An embodiment of a stage device comprises a chuck (e.g., an electrostatic chuck) that performs adhesion-chucking of a wafer or other substrate that has been transported to the chuck by a transport robot or the like. The chuck includes an adhesion-chucking face that faces upward and is mounted on a fine-movement table. The fine-movement table is mounted on a coarse-movement stage. The stage device also includes at least one support member mounted on the coarse-movement stage. The support member extends upward and supports the substrate from below whenever the substrate is detached from the adhesion-chucking face of the chuck and the fine-movement table is in a lowered position.

In an embodiment each support member is situated in a respective feed-through hole defined in and extending vertically in the chuck. For example, the support member(s) can be situated in respective feed-through hole(s) defined vertically in the fine-movement table. The feed-through holes can be defined in three or more places, wherein each feed-through hole has a respective supporting member situated therein.

The stage device can include position-measurement means for measuring the positional relation between the substrate, supported by the support member(s), and the fine-movement table. The stage device can also include positioning means for moving the fine-movement table such that the positional relationship between the substrate and the fine-movement table is determined in advance. The positioning means can be configured to move the fine-movement table rotationally within a horizontal plane. The positioning means also can be configured, after moving the fine-movement table, to raise the fine-movement table so as to place the substrate on the adhesion-chucking face of the chuck.

The stage device can include removal means that lowers the fine-movement table so that the support member(s) can detach the substrate from the adhesion-chucking face.

The stage device can include a force-measurement means for measuring forces acting on the support member(s). In this embodiment, as the removal means lowers the fine-movement table to detach the substrate from the chucking face, the force-measurement means measures the resulting forces being applied to the support member(s) to ensure that the forces do not exceed a prescribed value.

Another aspect is directed to exposure systems that comprise a stage device as summarized above.

In the instant stage devices a support member(s) that supports the substrate in the upward direction, whenever the fine-movement table is in a lowered position, is mounted on the coarse-movement stage, so that the accuracy and precision with which the substrate can be adhesion-chucked to the chuck is easily improved, while facilitating easy removal of the substrate from the chuck.

Also provided are exposure systems that include a stage device as summarized above. Thus, the accuracy and precision of exposure performed using the systems are improved through improvements in the accuracy and precision with which the substrate can be positioned on the chuck by adhesion-chucking. Also, removal of the substrate from the chuck is facilitated, which improves throughput.

### BRIEF DESCRIPTION OF THE DRAWINGS

FIG. 1 is a schematic elevational view of a first representative embodiment of a stage device.

FIG. 2 is a plan view of the fine-movement table of the stage device of FIG. 1.

FIG. 3 is a schematic elevational view of the stage device of FIG. 1, to which a wafer is being transported by a robotic transport arm.

FIG. 4 is a schematic elevational view of the stage device of FIG. 1, in a state in which the positions of the wafer and of the fine-movement table are adjusted.

FIG. 5 is a plan view of an exemplary wafer on the stage device of FIG. 1, and showing image-processing devices used in pre-alignment of the wafer.

FIG. 6 is a schematic elevational view showing details of an image-processing device as used in the configuration shown in FIG. 5.

FIG. 7 is a schematic plan view showing the state of the fine-movement table shown in FIG. 4.

FIG. 8 is a schematic elevational view of the stage device of FIG. 1, showing a state in which the wafer is being removed from the chuck.

FIG. 9 is a flowchart of steps in an operational process for the stage device of FIG. 1.

FIGS. 10(A)-10(G) are a series of respective schematic elevational views corresponding to certain steps in the operational process diagrammed in FIG. 9.

FIG. 11 is a schematic elevational view of a stage device according to a second representative embodiment.

FIG. 12 is a schematic diagram of an embodiment of an exposure system comprising a stage device as described herein.

### DETAILED DESCRIPTION

Representative embodiments are described below, with reference to the drawings.

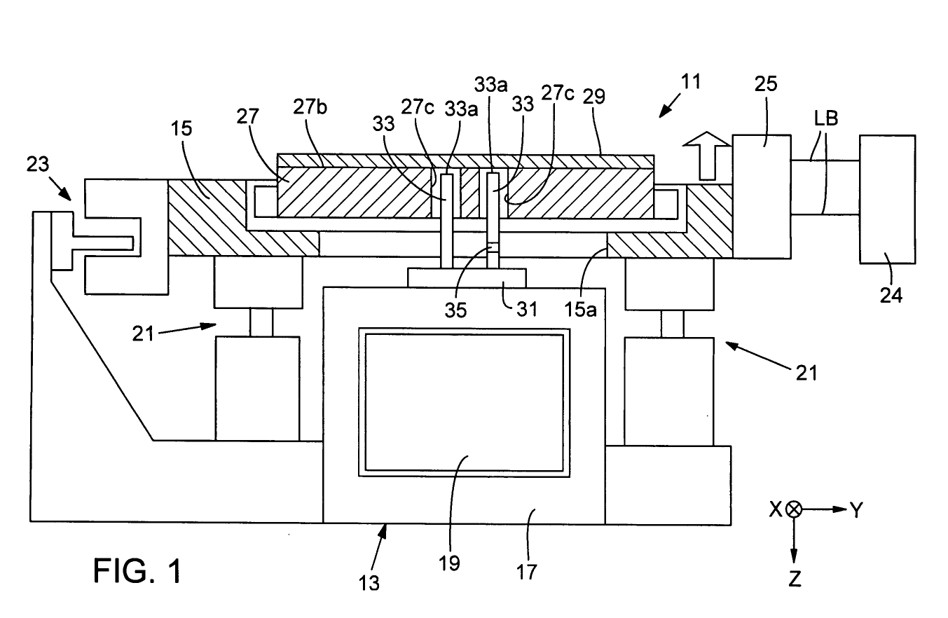

A first representative embodiment is depicted in FIG. 1, which shows a stage device configured to hold a wafer or other exposure substrate (generally called a “wafer”). Hence, the depicted stage device is a “wafer stage” 11. The wafer stage 11 comprises a coarse-movement stage 13 and a fine-movement table 15. The coarse-movement stage 13, which moves in a direction perpendicular to the plane of the page (i.e., moves in the X direction), includes a main portion 17 that is guided by a guide post 19. The coarse-movement stage 13 also can move in the lateral direction in the plane of the paper (i.e., moves in the Y direction) by means of a guide mechanism (not shown). The accuracy and precision with which the coarse-movement stage 13 can be positioned in the X direction and Y direction is in the micron range.

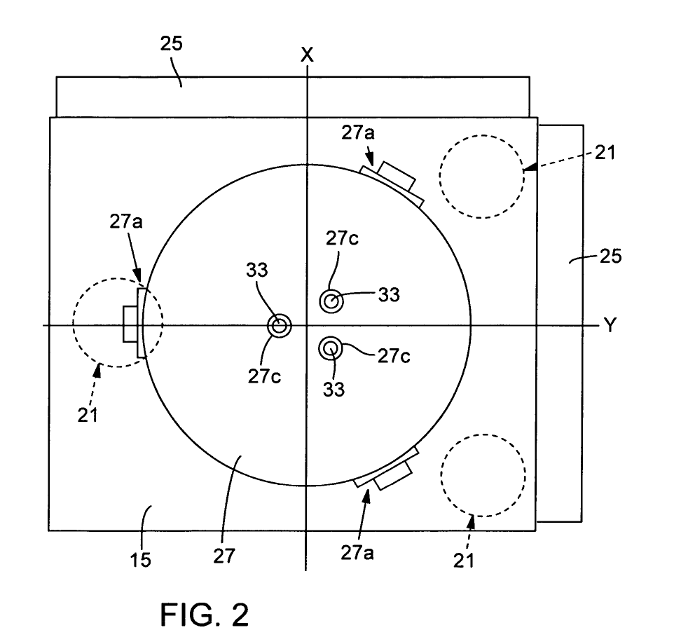

The fine-movement table 15 is situated above the main portion 17 of the coarse-movement stage 13. The fine-movement table 15 is supported by Z-actuators 21 placed on both sides of the main portion 17. As indicated in FIG. 2, three Z-actuators 21 are positioned in a triangular arrangement (but four or more may be used, in which the arrangement need not be triangular). The Z-actuators 21 incorporate respective displacement encoders, and impart fine movements of the fine-movement table 15 in the vertical direction (Z direction) in the drawing.

The fine-movement table 15 also undergoes fine movement in the X direction and Y direction by means of XY-actuators 23. Three or more XY-actuators 23 (each of which comprising, for example, a respective voice-coil motor) are positioned between the fine-movement table 15 and the coarse-movement stage 13. The fine-movement table 15 also is capable of rotation about the X-axis, the Y-axis, and the Z-axis. That is, the fine-movement table 15 can be driven with six degrees of freedom (X, Y, Z, θₓ, _74 _{y}, θ_{z}). The accuracy and precision of movements of the fine-movement table 15 are in the nanometer range.

On the outer periphery of the fine-movement table 15 is positioned a moving mirror 25 used for measuring, by means of laser light LB from a laser interferometer 24, the position of the fine-movement table 15.

Above the fine-movement table 15 is positioned a chuck 27 (e.g., an electrostatic chuck). The chuck 27 is mounted to the fine-movement table 15 by bolts or other means at fastening portions 27a in three locations, as shown in FIG. 2. The upper surface of the chuck 27 is an adhesion-chucking face 27b for adhesion-chucking of a wafer 29.

A fastening plate 31 is mounted to the upper surface of the main portion 17 of the coarse-movement stage 13. Mounted on the fastening plate 31 are support members 33 that support the wafer 29 in the upward direction relative to the chuck 27 whenever the fine-movement table 15 is sufficiently lowered relative to the support members 33. The support members 33 in this embodiment are shaped as respective pins, as shown in FIG. 2. In this embodiment three support members 33 are arranged in a triangular pattern that is concentric with the circular-shaped chuck 27.

Feed-through holes 27c are defined in the vertical direction in three locations in the chuck 27, at respective positions corresponding to the support members 33. The support members 33 extend into their respective feed-through holes 27c via an opening 15a defined in the fine-movement table 15. The inside diameter of each feed-through hole 27c is larger than the outside diameter of the respective support member 33. Thus, fine movements of the fine-movement table 15 do not cause physical interference of the chuck 27 with the support members 33. The upper ends 33a of the support members 33 are situated below the adhesion-chucking face 27b of the chuck 27 whenever the fine-movement table 15 is in a raised position, and protrude upward from the adhesion-chucking face 27b of the chuck 27 whenever the fine-movement table 15 is in a lowered position.

A force sensor 35, which measures the force acting on the support members 33, is mounted on at least one of the support member 33. The force sensor 35 comprises, for example, a piezoelectric element, strain gauge, or the like.

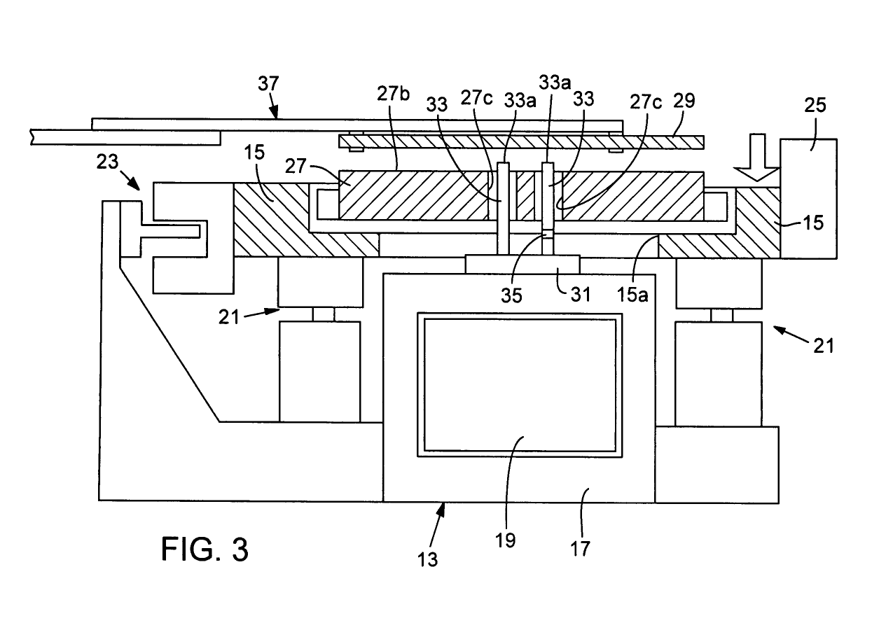

FIG. 3 depicts a situation in which the fine-movement table 15 of the wafer stage 11 has been lowered by the Z-actuators 21 relative to the support members 33. Consequently, the support members 33 protrude upward from the adhesion-chucking face 27b of the chuck 27. Meanwhile, the wafer 29 is being conveyed to the wafer stage 11 by a robotic transport arm 37.

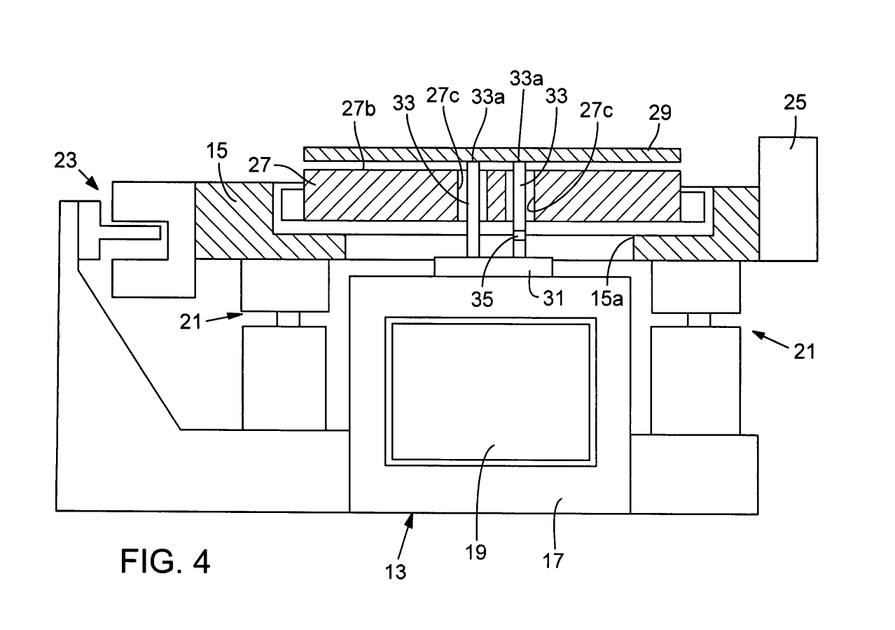

In FIG. 4, the wafer 29 has been placed by the robotic transport arm 37 on the upper ends 33a of the support members 33, and the transport arm has been moved away. With the wafer 29 positioned in this manner, pre-alignment of the wafer 29 and of the fine-movement table 15 can be performed. Pre-alignment is performed using image-processing devices 38, 40 (FIG. 5) to measure the position of the wafer 29 supported by the upper ends 33a of the support members 33. The image-processing devices 38, 40 desirably are off-axis-type two-dimensional image-processing devices, and are positioned in proximity to one end of the projection-optical system (not shown) on the wafer side.

As shown in FIG. 5, the image-processing device 38 is positioned on a line extending parallel to the Y-axis and passing substantially through the center of the notch N of the wafer 29, while the image-processing device 40 is positioned on a line extending parallel to the X-axis and passing substantially through the center of the wafer 29.

FIG. 6 is an elevational view of the image-processing device 38. Illuminating light (having a wavelength within a band at which a photoresist applied to the wafer 29 has at most a weak photosensitivity) is emitted from a light-emitting diode (LED) or other light source 42. The illuminating light is incident on one end of an optical fiber or other optical guide 44. The illuminating light emitted from the other end of the optical guide 44 passes through a collimating lens 46, a half-prism 48, and an objective lens 50 to irradiate an edge portion at the outer periphery of the wafer 29 supported on the upper ends 33a of the support members 33. Light reflected from the edge portion passes through the objective lens 50, the half-prism 48, and a focusing lens 52 and is incident on an image-capture element 54 comprising a two-dimensional CCD or the like. Thus, an image of the edge portion of the wafer 29 is formed on the image-sensing surface of the image-capture element 54. The configuration of the image-processing device 40 is similar to that of the image-processing device 38, and is not described further.

The position of the notch N of the wafer 29 for detection is determined from captured-image signals that are output from the respective image-capture elements 54 of the image-processing devices 38 and 40. Prescribed computational processing is performed (by, e.g., a processor, not shown) to calculate the wafer-rotation angle and amounts of translational movement of the wafer that are necessary for achieving wafer pre-alignment. The fine-movement table 15 is then moved, based on the calculated values, to achieve wafer pre-alignment. Meanwhile, because the inside diameters of the feed-through holes 27c in the chuck 27 are sufficiently greater than the outside diameters of the support members 33, the chuck 27 does not physically interfere with the support members 33 accompanying these motions of the fine-movement table 15.

Next, the fine-movement table 15 is raised by the Z-actuators 21, as shown in FIG. 1. Thus, the upper ends 33a of the support members 33 retract within the feed-through holes 27c in the chuck 27 while placing the wafer 29 on the adhesion-chucking face 27b of the chuck 27. Then, the chuck 27 is energized or otherwise turned on, and the wafer 29 is adhesion-chucked by the chuck 27. While the wafer is being held in this manner, accurate positioning (fine alignment) of the fine-movement table 15 is performed. Prior to performing fine alignment, the fine-movement table 15 is returned an “original” horizontal position in the XY plane (XY-position). This return is performed by moving the fine-movement table 15 through a wafer-rotation angle and an amount of translational movement that were calculated during pre-alignment processing. Meanwhile, the position of the fine-movement table 15 is measured using the laser interferometer 24.

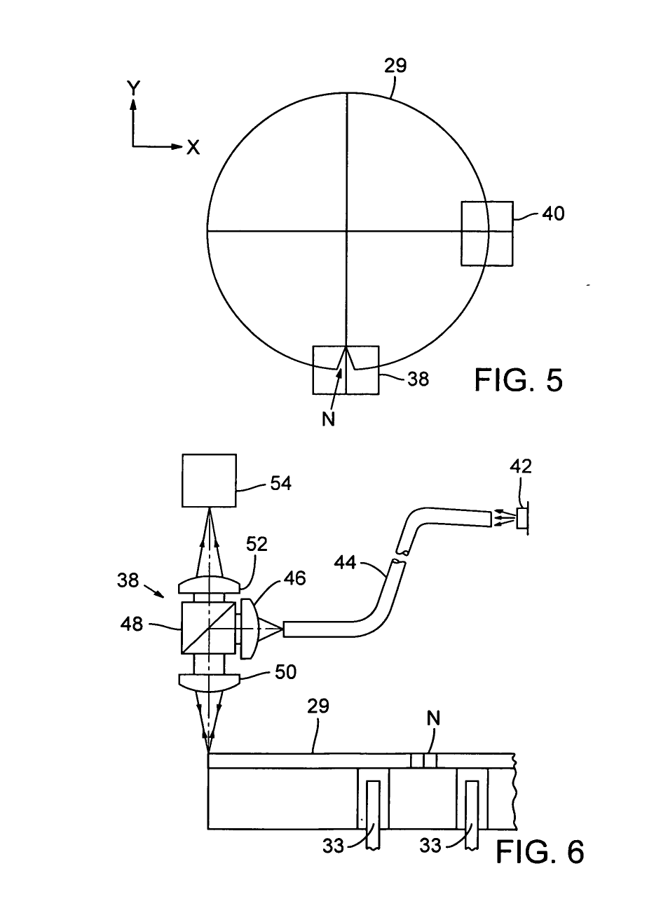

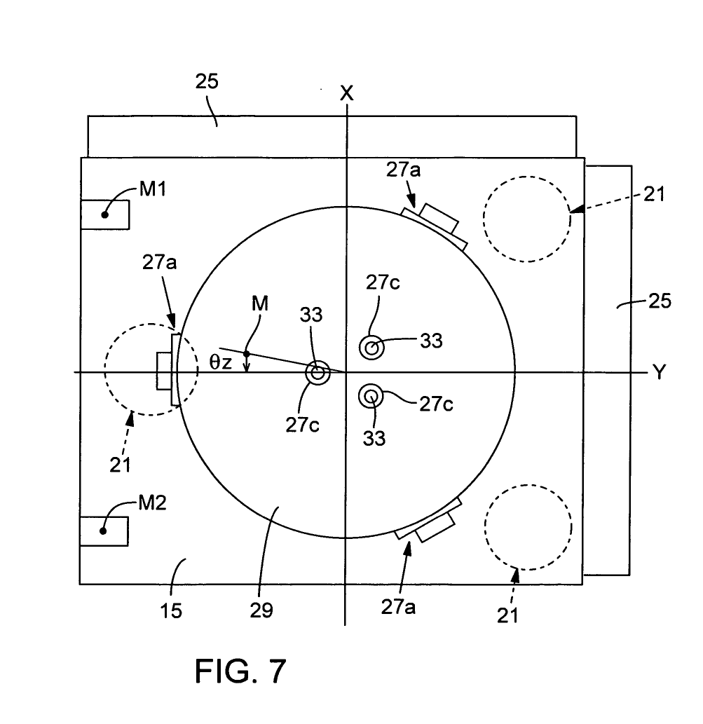

As shown in FIG. 7, fine alignment of the fine-movement table 15 is performed by measuring the positional relationship of the wafer 29 (adhesion-chucked on the chuck 27) and the fine-movement table 15. In this measurement, for example, a reference microscope (not shown) is used to measure the relative positions of fiducial marks M1, M2, formed on the fine-movement table 15, and an alignment mark M formed on the wafer 29. Then, the fine-movement table 15 is moved until the relative positional relationship between the alignment mark M on the wafer 29 and the fiducial marks M1, M2 on the fine-movement table 15 is according to a predetermined positional relationship. This movement is performed by fine movements of the fine-movement table 15 in the X direction and Y direction performed by the XY-actuator 23, and by rotations of the fine-movement table 15 by a prescribed angle (θ_{z}) about the center (Z axis) in the horizontal plane.

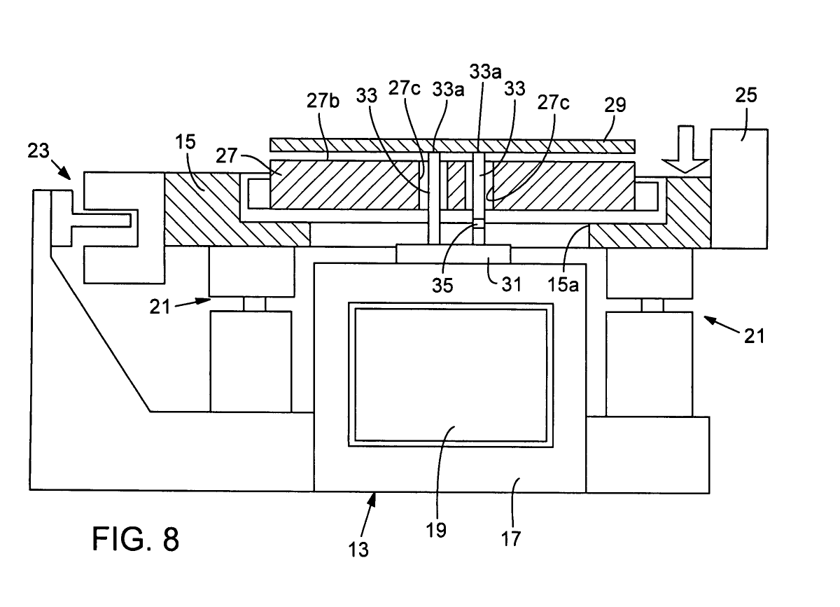

After performing exposure of the wafer, the chuck 27 is turned off to relieve the force holding the wafer 29 to the adhesion-chucking face 27b of the chuck 27. Substantially at the same time, the fine-movement table 15 is lowered to cause the support members 33 to extend above the adhesion-chucking face 27b of the chuck 27 (FIG. 8). Thus, the wafer 29 is forcibly released from the adhesion-chucking face 27b against any residual adhesive force being applied by the chuck 27 to the wafer. During this removal of the wafer from the adhesion-chucking face 27b, the force acting on the support members 33 is measured by the force sensor 35. This force data impacts the rate at which the fine-movement table 15 is lowered to ensure that the force acting on the support members 33 does not exceed a prescribed value (notably, does not exceed a magnitude that would damage the wafer 29). Thus, the wafer 29 is not exposed to excessive force, and wafer damage is prevented.

Then, the wafer 29, having been separated from the adhesion-chucking face 27b of the chuck 27, is picked up and transported by the robotic transport arm 37 (FIG. 3) to a storage location for the wafer 29.

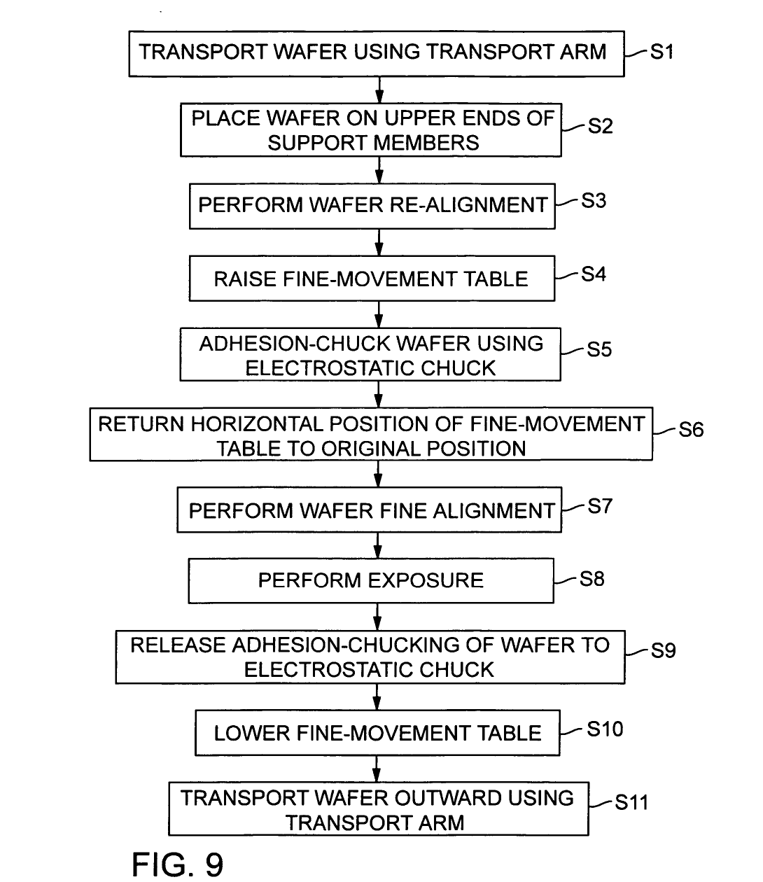

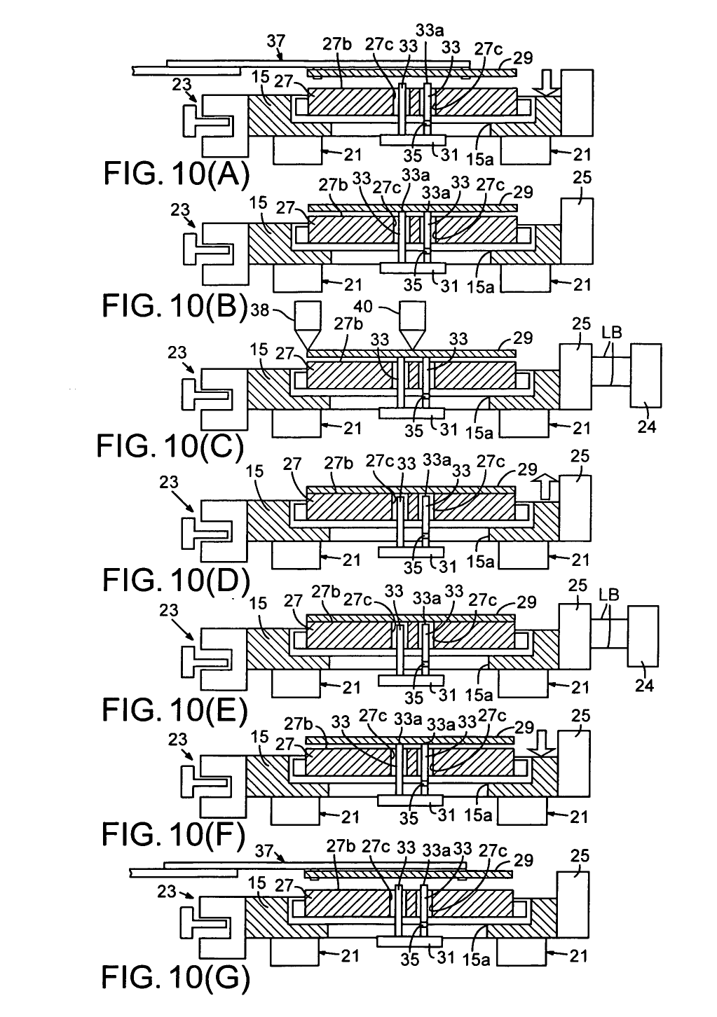

FIGS. 9 and FIG. 10 depict set forth steps in a process that includes pre-alignment and fine alignment of the wafer 29 using an embodiment of a wafer stage that includes an electrostatic chuck. FIG. 9 is a process flowchart that articulates the series of steps, and FIG. 10 provides respective diagrams of the steps. In step S1 the wafer 29 is delivered to the wafer stage 11 by the transport arm 37. At this time, as shown in FIG. 10(A), the fine-movement table 15 has been lowered by the Z-actuators 21 to cause the support members 33 to protrude upward from the adhesion-chucking face 27b of the chuck 27. In step S2 the wafer 29 has been placed by the transport arm on the upper ends 33a of the support members 33, as shown in FIG. 10(B). In step S3 pre-alignment of the wafer 29 is performed, as shown in FIG. 10(C), using the image-processing devices 38, 40 to measure the position of the wafer 29 supported on the upper ends 33a of the support members 33. From the position data, the rotation angle and amount of translational movement of the wafer 29 necessary for pre-alignment are calculated, and the fine-movement table 15 is moved based on these calculated values. Movement of the fine-movement table 15 is performed while using the laser interferometer 24 to measure the position of the fine-movement table 15. In step S4 the fine-movement table 15 is raised by the Z-actuators 21. Thus, as shown in FIG. 10(D), the upper ends 33a of the support members 33 retract into the feed-through holes 27c, thereby placing the wafer 29 on the adhesion-chucking face 27b of the chuck 27. In step S5 the chuck 27 is turned on to cause the wafer 29 to adhere to the adhesion-chucking surface 27b. In step S6 the horizontal position (XY-direction position) of the fine-movement table 15 is returned to the original position. As shown in FIG. 10(E), this operation is performed by moving the fine-movement table 15 by the rotation angle and amount of translational movement of the wafer 29 that were determined at the time of pre-alignment; meanwhile, the laser interferometer 24 is used to measure the position of the fine-movement table 15. In step S7 fine alignment of the wafer 29 is performed. As shown in FIG. 7, this fine alignment is performed by moving the fine-movement table 15 until the relative positional relationship between the alignment mark M of the wafer 29 and the fiducial marks M1, M2 of the fine-movement table 15 are according to a predetermined positional relationship. In step S8 the wafer 29 is exposed. In step S9 the chuck 27 is turned off, thereby alleviating the adhesion force of the wafer 29 to the adhesion-chucking face 27b. In step S10 the fine-movement table 15 is lowered by the Z-actuators 21. Thus, as shown in FIG. 10(F), the support members 33 are made to protrude from the adhesion-chucking face 27b of the chuck 27, which forcibly detaches the wafer 29 from the adhesion-chucking face 27b in opposition to any residual adhesion force being produced by the chuck 27. In step S11 the wafer 29 is picked up and transported away by the transport arm 37, as shown in FIG. 10(G).

Thus, a series of process steps, including pre-alignment and fine alignment of the wafer 29, is completed, after which steps S1 through S11 are repeated as required for the next wafer.

In the wafer stage 11 of this embodiment, the support members 33 are mounted to the coarse-movement stage 13 to support, in the upward direction from the chuck 27, the wafer 29 whenever the fine-movement table 15 is in a lowered position. Thus, the positional relationship between the wafer 29 and the fine-movement table 15 can be adjusted in the state in which the wafer 29 is placed on the support members 33. Hence, whenever the wafer 29 is being adhesion-chucked onto the chuck 27, the positional relationship between the wafer 29 and the fine-movement table 15 can be adjusted, which improves the positional accuracy and precision with which the wafer 29 is adhesion-chucked by the chuck 27. Also, during transport (by the transport arm 37 and in a vacuum environment) of the wafer to the wafer stage 11, high accuracy and precision of positioning of the wafer onto the wafer stage are achieved even if the rigidity of the transport arm 37 is comparatively weak.

Further with respect to this embodiment, whenever the fine-movement table 15 is being lowered relative to the support members 33, the support members are made to extend upward from the adhesion-chucking face 27b of the chuck 27. These protruding support members forcibly detach the wafer 29 from the adhesion-chucking face 27b, in opposition to any residual adhesion force being produced by the chuck 27. Thus, removal of the wafer 29 from the chuck 27 is facilitated, and throughput is improved.

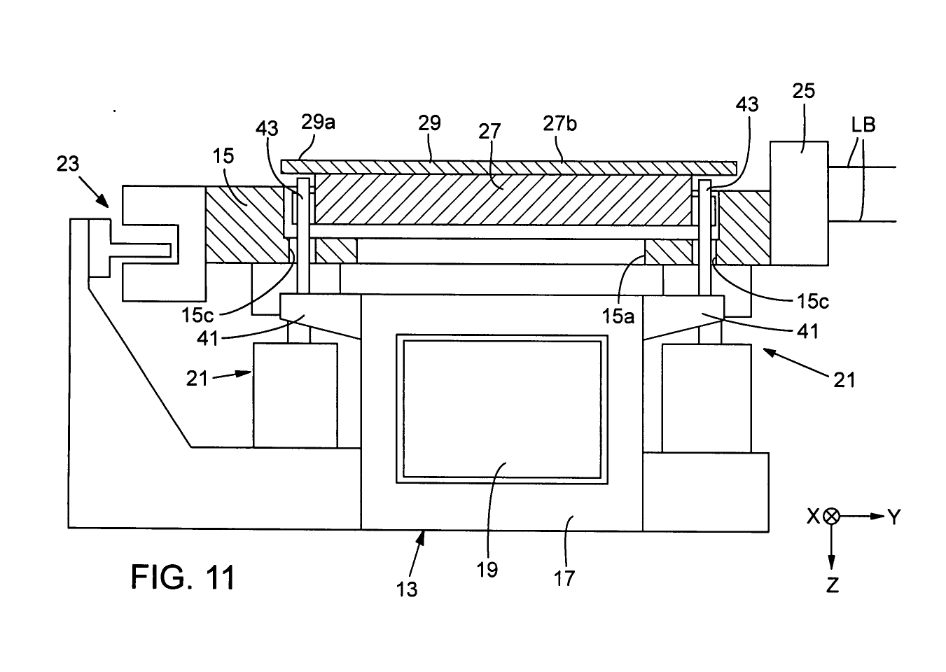

A stage device according to a second representative embodiment is depicted in FIG. 11. Components in this embodiment that are the same as in the first embodiment have the same reference numerals and are not described further.

In this embodiment three brackets 41 are mounted, at prescribed angles, to the side face of the main portion 17 of the coarse-movement stage 13. Support members 43 are mounted on the respective upper faces of each of the brackets 41. Feed-through holes 15c, through which the support members 43 extend, are defined in the fine-movement table 15 at positions corresponding to the support members 43. The chuck 27 (e.g., electrostatic chuck) is fastened inwardly of the feed-through holes 15c of the fine-movement table 15. The chuck 27 has a diameter that is smaller than the outside diameter of the wafer 29. The outer periphery 29a of the wafer 29 extends over the outside edge of the chuck 27.

In this embodiment the outer periphery 29a of the wafer 29 is placed on the support members 43 by lowering the fine-movement table 15. In this state the positional relationship between the wafer 29 and fine-movement table 15 can be measured and adjusted. By lowering the fine-movement table 15, the support members 43 are made to protrude from the adhesion-chucking face 27b of the chuck 27, which serves to detach the wafer 29 forcibly from the adhesion-chucking face 27.

This second representative embodiment achieves advantageous results that are substantially the same as the first embodiment.

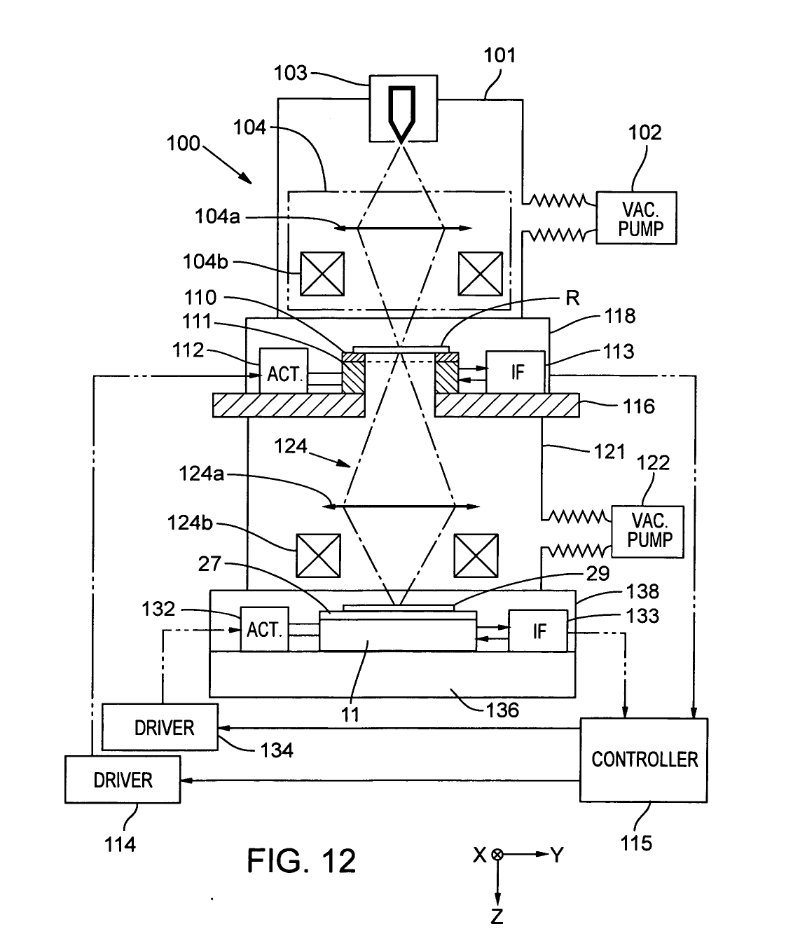

FIG. 12 shows a representative embodiment of an electron-beam exposure system 100, as a representative exposure system, that comprises a wafer stage 11 as described above. In this embodiment an optical column 101 of an illumination-optical system is situated in the upper portion of the electron-beam exposure device 100. A vacuum pump 102 is connected to the optical column 101 and evacuates the interior of the optical column 101 to a suitable vacuum. In the upper portion of the optical column 101 is an electron gun 103 that emits an electron beam directed downward in the figure. Downstream of the electron gun 103 is an illumination-optical system 104 that comprises a condenser lens 104a and an electron-beam deflector 104bIn the figure the condenser lens 104a is shown as being a single lens stage; but an actual illumination-optical system comprises a plurality of lenses, beam-shaping apertures, and the like.

In the lower portion of the optical column 101 of the illumination-optical system is a reticle chamber 118 that is mounted on a base 116. The interior of the reticle chamber 118 is evacuated to a suitable vacuum by a vacuum pump (not shown). Contained within the reticle chamber 118 is a reticle stage 111 that is mounted on the base 116. The reticle R is fastened, by electrostatic chucking or the like, to a reticle chuck 110 mounted on the upper portion of the reticle stage 111. A stage-actuating device 112, shown on the left in the drawing, is connected to the reticle stage 111. (An actual stage-actuating device 112 is incorporated into the reticle stage 111.) The stage-actuating device 112 is connected, via a driver 114, to a controller 115. The reticle stage 111 includes a laser interferometer 113, shown on the right in the drawing. The laser interferometer 113 is connected to the controller 115. Position data for the reticle stage 111, measured by the laser interferometer 113, is input into the controller 115, whereupon an instruction is sent from the controller 115 to the driver 114, which causes the stage-actuating device 112 to position the reticle stage 111 at a target position. Thus, accurate feedback control of the position of the reticle stage 111 is achieved in real time.

The electron beam emitted from the electron gun 103 is made to converge by the condenser lens 104a onto the surface of the reticle R as the reticle remains adhesion-chucked onto the reticle stage 111 in the reticle chamber 118. The beam is scanned in the horizontal direction in the figure by the deflector 104b so as to illuminate, in a sequential manner, each of the small exposure areas (subfields) of the reticle R located within the optical field of the illumination-optical system.

An optical column 121 for a projection-optical system is situated downstream of the base 116. The optical column 121 of the projection-optical system is connected to a vacuum pump 122 that evacuates the interior of the optical tube 121 to a suitable vacuum. Within the optical tube 121 is the projection-optical system 124, which comprises a condenser lens (projection lens) 124a, a deflector 124b, and the like, and also the wafer 29. In the figure, the condenser lens 124a is shown as a single lens stage, but an actual projection-optical system 124 comprises a plurality of stages of lenses and aberration-correcting lenses and coils.

In the lower portion of the optical column 121 of the projection-optical system is a wafer chamber 138 that is mounted on a base 136. The interior of the wafer chamber 138 is evacuated to a suitable vacuum by a vacuum pump (not shown). The wafer stage 11 is mounted on the base 136 in the wafer chamber 138. The wafer stage 11 is configured similarly to the wafer stage shown in FIG. 1, for example. The wafer 29 is mounted by electrostatic adhesion to the chuck 27 provided in the upper portion of the wafer stage 11. The wafer stage 11 is connected to an actuator 132, shown on the left in the figure (an actual actuator 132 is incorporated within the wafer stage 11). The actuator 132 is connected, via a driver 134, to the controller 115.

The wafer stage 11 comprises a laser interferometer 133, shown on the right in the figure. The laser interferometer 133 is connected to the controller 115. Whenever positional information for the wafer stage 11, as measured by the laser interferometer 133, is input to the controller 115, an instruction is sent from the controller 115 to the driver 134, with the position of the wafer stage 11 as a target position, and the actuator 132 is driven accordingly. As a result, the position of the wafer stage 11 is subjected to accurate real-time feedback control.

The electron beam, having passed through the reticle R on the reticle stage 111 in the reticle chamber 118, is converged by the condenser lens 124a within the optical column 121 of the projection-optical system. The converged electron beam is deflected by the deflector 124b to place an image of the illuminated portion of the reticle R on a prescribed position on the wafer 29. Thus, the wafer 29 is exposed.

In this embodiment of an exposure system, the wafer stage 11 as described herein is used, so that exposure accuracy and precision are improved. This is achieved by improving the accuracy and precision with which the wafer 29 is positioned (by adhesion-chucking) to the chuck 27. Also, removal of the wafer 29 from the chuck 27 is simplified, which improves throughput.

The invention has been described in the context of representative embodiments.

But, it will be understood that the scope of the invention is not limited to the described embodiments. By way of example, the following alternatives can be employed:

(1) In the embodiments described above, the wafer 29 is adhesion-chucked by an electrostatic chuck 27. Alternatively, the wafer can be adhesion-chucked using a vacuum chuck, for example.

(2) In the embodiments described above, delivery and removal of the wafer 29 by a robotic transport arm 37 are performed separately. Alternatively, a dual-action transport arm, for example, may be used, with wafer delivery and removal being performed substantially simultaneously.

(3) In the embodiments described above, the stage device was described as being a part of charged-particle-beam exposure system that utilized a charged particle beam (e.g., electron beam) as an energy beam. But, the particular energy beam with which the stage device is used is not limited to a charged particle beam. Alternatively, the energy beam can be, for example, visible light, ultraviolet light, X-rays (soft X-rays, EUV, and the like), and other charged particle beams (e.g., ion beams). The exposure method is not limited, and may be broadly applied to reduction projection-exposure, proximity transfer (no reduction or enlargement), direct-drawing, and other methods.

1-10. (canceled)

11. A stage device, comprising:
a coarse-movement stage;
a fine-movement table mounted to the coarse-movement stage so as to be movable relative to the coarse-movement stage;
at least one actuator, coupled to the coarse-movement stage and to the fine-movement table, configured to move the fine-movement table relative to the coarse-movement stage at least in a first motion from a lowered position to a raised position and from the raised position to the lowered position;
a chuck mounted on the fine-movement table, the chuck comprising an upward-facing adhesion-chucking face configured for holding a substrate; and
at least one support member mounted to and extending upward from the coarse-movement stage toward the adhesion-chucking face, the at least one support member being configured to contact the substrate from below and support the substrate relative to the adhesion-chucking face whenever the fine-movement table is in the lowered position, and to allow the substrate to rest on the adhesion-chucking face whenever the fine-movement table is in the raised position.

12. The stage device of claim 11, wherein the at least one actuator is further configured to perform a second motion of the fine-movement table relative to the coarse-movement stage, the second motion including at least a fine motion in a plane substantially perpendicular to the first motion.

13. The stage device of claim 12, wherein the actuator comprises at least one first actuator situated and configured to perform the first motion and at least one second actuator situated and configured to perform the second motion.

14. The stage device of claim 11, wherein the at least one support member extends upward, toward the adhesion-chucking face, from the coarse-movement stage through a respective, substantially vertical, feed-through hole defined in the chuck.

15. The stage device of claim 11, wherein the at least one support member extends upward, toward the adhesion-chucking face, from the coarse-movement stage through a void in the fine-movement table.

16. The stage device of claim 11, comprising at least three of the support members mounted to and extending upward from the coarse-movement stage toward the adhesion-chucking face.

17. The stage device of claim 16, comprising three support members mounted to and extending upward from the coarse-movement stage toward the adhesion-chucking face, the three support members being arranged so as to contact and support the substrate in a tripod manner from below whenever the fine-movement table is in the lowered position.

18. The stage device of claim 17, wherein the three support members extend upward, toward the adhesion-chucking face, through respective, substantially vertical, feed-through holes defined in the chuck.

19. The stage device of claim 17, wherein the three support members extend upward, toward the adhesion-chucking face, from the coarse-movement stage through at least one void in the fine-movement table.

20. The stage device of claim 16, wherein:
each support member has a respective pin configuration; and
each support member extends upward, toward the adhesion-chucking face, through a respective, substantially vertical feed-through hole defined in the chuck.

21. The stage device of claim 16, wherein:
each support member has a respective pin configuration; and
the support members extend upward from the coarse-movement stage through at least one void in the fine-movement table.

22. The stage device of claim 11, further comprising a position-measurement device situated and configured to measure a position of the substrate, supported by the at least one support member, relative to the fine-movement table.

23. The stage device of claim 22, wherein:
the at least one actuator comprises at least one first actuator situated and configured to perform the first motion; and
the at least one actuator comprises at least one second actuator situated and configured to perform a second motion of the fine-movement table, relative to the coarse-movement stage and based on the measured position of the substrate, to establish a positional relationship between the substrate and the fine-movement table according to a predetermined positional relationship.

24. The stage device of claim 23, wherein the second motion includes a rotational motion in a horizontal plane.

25. The stage device of claim 23, wherein the at least one first actuator is configured to move the fine-movement table, after the fine-movement table has undergone the second motion, in the first motion from the lowered position to the raised position to place the substrate on the adhesion-chucking face.

26. The stage device of claim 25, wherein:
the chuck is operable in a first state in which the adhesion-chucking face is producing a chucking force to cause the substrate to adhere to the adhesion-chucking face and in a second state in which the adhesion-chucking face is not producing the chucking force; and
the at least one first actuator is configured, when the chuck is operating in the second state, to move the fine-movement table in the first motion from the raised position to the lowered position to cause the at least one support member to contact the substrate from below in a manner serving to detach the substrate from the adhesion-chucking face.

27. The stage device of claim 26, further comprising a force-measurement device situated and configured to detect and measure a force acting on at least one support member, wherein the at least one first actuator moves the fine-movement table in the first motion from the raised position to the lowered position in a manner such that a force applied by the at least one support member to the substrate does not exceed a prescribed magnitude.

28. An exposure device, comprising a stage device as recited in claim 11.

29. The exposure device of claim 28, further comprising a transport arm situated and configured to place a substrate on the stage device and to remove the substrate from the stage device.

30. A stage device, comprising:
a coarse-movement stage;
a fine-movement table mounted to the coarse-movement stage so as to be movable relative to the coarse-movement stage;
a chuck mounted on the fine-movement table, the chuck comprising an upward-facing adhesion-chucking face configured for holding a substrate;
at least one Z-actuator situated and configured to move the fine-movement table relative to the coarse-movement stage in a Z-direction from a lowered position to a raised position and from the raised position to the lowered position;
at least one fine-actuator situated and configured to impart a fine motion to the fine-movement table relative to the coarse-movement stage, the fine motion including motion in an XY plane perpendicular to the Z-direction; and
multiple support members mounted to and extending upward from the coarse-movement stage toward the adhesion-chucking face, the support members being configured to contact the substrate from below and support the substrate relative to the adhesion-chucking face whenever the fine-movement table is in the lowered position, and to allow the substrate to rest on the adhesion-chucking face whenever the fine-movement table is in the raised position.

31. The stage device of claim 30, wherein the chuck is an electrostatic chuck.

32. The stage device of claim 30, wherein the support members are arranged to support the substrate, whenever the fine-movement table is in the lowered position, in a tripod manner.

33. The stage device of claim 30, wherein the support members are configured as respective pins that extend upward, toward the adhesion-chucking face, through respective, substantially vertical feed-through holes defined in the chuck.

34. The stage device of claim 30, wherein the support members extend upward, toward the adhesion-chucking face, through a void in the fine-movement table.

35. The stage device of claim 30, further comprising a force-measuring device situated and configured to measure a force applied by the support members to the substrate at least whenever the fine-movement table, being lowered by the Z-actuators and carrying the substrate situated on the adhesion-chucking face, has lowered sufficiently to cause the support members to contact the substrate from below.

36. The stage device of claim 30, further comprising a position-measurement device situated and configured to measure a position of the substrate supported by the support members, wherein the at least one fine-actuator moves the fine-movement table as required to establish a positional relationship between the substrate and the fine-movement table according to a predetermined positional relationship.

37. An exposure apparatus, comprising a stage device as recited in claim 30.

38. The exposure apparatus of claim 37, further comprising a transport arm situated and configured to place a substrate on the stage device and to remove the substrate from the stage device.

39. A stage device, comprising:
chuck means comprising holding-surface means for holding a substrate;
fine-movement table means for holding the chuck means;
first actuator means for imparting fine movements of the fine-movement table means;
coarse-movement stage means for supporting the fine-movement table means and for performing coarse motions of the coarse-movement stage means and hence of the fine-movement table means;
second actuator means for moving the fine-movement table means with chuck means relative to the coarse-movement stage means in a Z-direction from a lowered position to a raised position and from the raised position to the lowered position; and
support-member means for contacting the substrate from below and supporting the substrate relative to the holding-surface means whenever the second actuator means has moved the fine-movement table means to the lowered position, and for allowing the substrate to rest on the holding-surface means whenever the second actuator means has moved the fine-movement table means to the raised position.

40. The stage device of claim 39, further comprising force-measuring means for measuring a force applied to the substrate whenever the fine-movement table means, being lowered by the second actuator means and carrying the substrate situated on the holding-surface means, has lowered sufficiently to cause the support-member means to contact the substrate from below.

41. The stage device of claim 39, further comprising position-measurement means for measuring a position of the substrate, supported by the support-member means, relative to the fine-movement table means, wherein the first actuator means moves the fine-movement table means as required to establish a positional relationship between the substrate and the fine-movement table means according to a predetermined positional relationship.

42. An exposure apparatus, comprising a stage device as recited in claim 39.

43. The exposure apparatus of claim 42, further comprising a transport arm situated and configured to place a substrate on the stage device and to remove the substrate from the stage device.

44. A method for holding a substrate, comprising:
placing the substrate at a position above an adhesion-chucking face of a chuck mounted on a fine-movement table that is mounted on a coarse-movement stage;
lowering the fine-movement table relative to the coarse-movement stage to cause at least one support member to protrude above the adhesion-chucking face;
placing the substrate on the at least one support member;
raising the fine-movement table relative to the coarse-movement stage to lower the at least one support member relative to the adhesion-chucking face and thus place the substrate on the adhesion-chucking face; and
activating the adhesion-chucking face to cause the substrate to adhere to the adhesion-chucking face.

45. The method of claim 44, further comprising, before raising the fine-movement table:
measuring a position of the substrate that has been placed on the at least one support member;
from the measured position, determining an amount and type of movement required of the substrate to achieve pre-alignment of the substrate; and
moving the fine-movement table according to the determined amount and type of movement.

46. The method of claim 45, further comprising:
fine-aligning the substrate; and
performing a process step on the substrate.

47. The method of claim 46, further comprising:
de-activating the adhesion-chucking face;
lowering the fine-movement table relative to the coarse-movement stage to cause the at least one support member to protrude above the adhesion-chucking face, thereby lifting the substrate from the adhesion-chucking face; and
removing the substrate from the at least one support member.

48. The method of claim 47, further comprising:
as the fine-movement is being lowered, measuring a force being applied to the at least one support member;
as the at least one support member contacts the substrate from below, if the measured force exceeds a predetermined magnitude, changing a rate at which the fine-movement table is being lowered to avoid applying excessive force to the substrate as the substrate is being lifted from the adhesion-chucking face by the at least one support member.
